(19) United States
(12) Patent Application Publication
(10) Pub. No.: US 2005/0184355 A1
(43) Pub. Date: Aug. 25, 2005

(54) Semiconductor device

(75) Inventor: Tetsuya Okada, Kumagaya-city (JP)

Correspondence Address: Barry E. Bretschneider;Morrison & Foerster LLP, Suite 300, 1650 Tysons Boulevard, McLean, VA, 22102, US

(73) Assignee: Sanyo Electric Co., Ltd., Moriguchi-city (JP)

(21) Appl. No.: 11/063,739

(22) Filed: Feb. 24, 2005

(30) Foreign Application Priority Data
Feb. 24, 2004 (JP) 2004-048258

(51) Int. Cl. H01L 29/00

(52) U.S. Cl. 257/510

(57) ABSTRACT

Conventionally, a guard ring for securing a breakdown voltage is provided around a Schottky barrier diode. Since the guard ring is a p+ type region, a depletion layer expands around the guard ring when a reverse voltage is applied to prevent a reduction in capacitance. In addition, there is a problem in that, when a forward voltage is applied, holes are injected from the guard ring if the applied voltage exceeds a predetermined voltage and high-speed operation cannot be realized. To solve the problems, a trench is provided in a guard ring region of the conventional technique and an insulating film is provided inside the trench. The trench is provided to reach an n+ type semiconductor substrate. Consequently, since the depletion layer expands only in a depth direction until the depletion layer reaches the n+ type semiconductor substrate, it is possible to realize a reduction in capacitance. In addition, since the p+ type region is made unnecessary, a reverse recovery time (Trr) does not occur. Therefore, it is possible to improve switching operation speed.

### BACKGROUND OF THE INVENTION

1. Field of the Invention

The present invention relates to a semiconductor device, and in particular to a semiconductor device that realizes a reduction in capacitance and high-speed switching of a Schottky barrier diode.

2. Description of the Related Art

FIGS. 4A and 4B show a conventional Schottky barrier diode D2. FIG. 4A is a plan view of the Schottky barrier diode D2 and FIG. 4B is a sectional view along line B-B in FIG. 4A. Note that Schottky metal layer and an anode electrode are not shown in the diagram view.

A substrate is obtained by stacking an n− type epitaxial layer 12b on an n+ type semiconductor substrate 12a. A metal layer 13, which forms a Schottky junction with the n− type epitaxial layer 12b, is provided on a surface of the n− type epitaxial layer 12b. The metal layer 13 is made of, for example, Mo. The metal layer 13 is provided in the opening of an insulating film 30 formed on the surface of the n− type epitaxial layer 12b. A region, where the metal layer 13 and the n− type epitaxial layer 12b are in contact with each other, is a Schottky junction region.

A guard ring 15, in which a p+ type impurity is diffused, is provided in an outermost periphery of the Schottky junction region in order to secure a predetermined breakdown voltage.

An anode electrode 16 consisting of Al or the like is provided to cover an entire surface of the metal layer 13 and a cathode electrode 17 is provided on a rear surface of the substrate. This technology is described for instance in Japanese Patent Application Publication No. Hei 6-224410 (page 2, FIG. 2).

Incidentally, as shown in FIGS. 4A and 4B, the conventional Schottky barrier diode D2 has a structure in which a depletion layer is expanded by providing the guard ring 15 in the periphery thereof to obtain the predetermined breakdown voltage.

In a Schottky barrier diode, a Schottky metal layer forming a Schottky junction with an n− type semiconductor layer is considered to be a pseudo p region. At the time when a reverse voltage is applied, a depletion layer expands from the Schottky junction region to the n− type semiconductor layer. For example, when a guard ring is not provided, a curvature of the depletion layer increases at an end of the Schottky junction region. Therefore, an electric field concentrates at the end of the Schottky junction region and the Schottky barrier diode breaks down.

Thus, as shown in FIG. 5, the p+ type guard ring 15 is provided at the end of the Schottky junction region. Consequently, a depletion layer 50 indicated by a broken line expands in a lateral (substrate horizontal) direction when the reverse voltage is applied. Therefore, a curvature of the depletion layer 50 at the end of the Schottky junction region relaxes, whereby the predetermined breakdown voltage can be obtained.

However, naturally, a depletion layer 50′ also expands to the periphery of the guard ring 15. Since the depletion layer 50′ becomes a capacitance component, there is a problem in that a reduction in capacitance of the Schottky barrier diode does not make progress.

In addition, there is also a problem in that the guard ring 15 prevents a high-speed operation. The guard ring 15 and the n− type epitaxial layer 12 form a pn junction. Since the guard ring 15 is also in contact with the metal layer 13, when a forward voltage is applied, this region operates as a pn junction diode if the voltage exceeds a predetermined voltage.

In general, a forward build-up voltage of the pn junction diode is about 0.6 V and a forward build-up voltage of the Schottky barrier diode is about 0.4 V. In addition, when an applied forward voltage exceeds about 0.65 V, forward voltage VF− forward current IF characteristics of both the diodes are reversed. In other words, although the pn junction diode never operates when the applied forward voltage is lower than about 0.6 V, when the applied forward voltage exceeds the voltage at which the forward voltage VF− forward current IF characteristics are reversed, the guard ring 15 portion operates as the pn junction diode, whereby the Schottky barrier diode D2 also operates simultaneously.

FIG. 6 shows an enlarged view of the guard ring 15 portion at the time when the forward voltage is applied in the Schottky barrier diode D2.

When the Schottky barrier diode D2 is used under the forward voltage larger than a certain voltage (e.g., 0.65 V) in an ON state, as described above, the guard ring 15 portion operates as the pn junction diode and carriers (holes) are injected into the n− type epitaxial layer 12b from the guard ring 15.

Thereafter, when the reverse voltage is applied in order to switch the Schottky barrier diode D2 to an OFF state, since carriers are accumulated in the n− type epitaxial layer 12b, outflow or recombination of the carriers accumulated in the epitaxial layer 12b is performed and, then, the depletion layer 50′ starts to expand. In other words, time for the outflow or the recombination of the carriers (reverse recovery time: Trr) is required before the Schottky barrier diode D2 comes into the OFF state.

There is a problem in that the reduction in capacitance does not make progress and the high-speed operation is prevented by providing the guard ring for securing a breakdown voltage.

### SUMMARY OF THE INVENTION

The invention provides a semiconductor device that includes a semiconductor substrate, a semiconductor layer disposed on the substrate, a metal layer forming a Schottky junction with the semiconductor layer to define a Schottky region, and a trench formed in the semiconductor layer to surround the Schottky region and reaching the semiconductor substrate, an inner wall of the trench being covered by an insulating film.

### BRIEF DESCRIPTION OF THE DRAWINGS

FIG. 1A is a plan view for explaining a semiconductor device according to an embodiment of the invention.

FIG. 1B is a sectional view for explaining the semiconductor device according to the embodiment of the invention.

FIG. 2 is a sectional view for explaining the semiconductor device according to the embodiment of the invention.

FIGS. 3A to 3C are sectional views for explaining a method of manufacturing the semiconductor device according to the embodiment of the invention.

FIG. 4A is a plan view for explaining a conventional semiconductor device.

FIG. 4B is a sectional view for explaining the conventional semiconductor device.

FIG. 5 is a sectional view for explaining the conventional semiconductor device.

FIG. 6 is a sectional view for explaining the conventional semiconductor device.

### DETAILED DESCRIPTION OF THE INVENTION

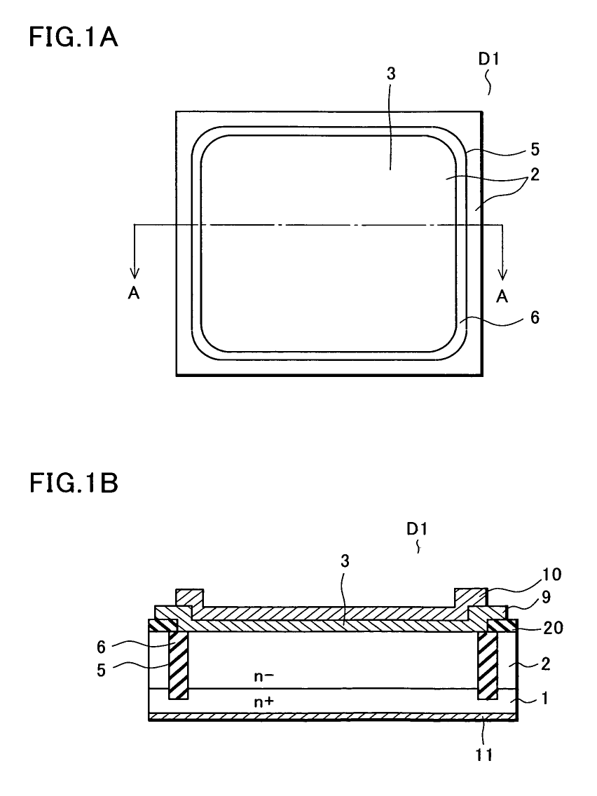

An embodiment of the invention will be explained in detail with reference to FIGS. 1A and 1B to FIGS. 3A to 3C.

FIGS. 1A and 1B show a Schottky barrier diode D1 according to the embodiment of the invention. FIG. 1A is a plan view of the Schottky barrier diode D1 and FIG. 1B is a sectional view along line A-A in FIG. 1A. Note that a Schottky metal layer and an anode electrode on a surface of the Schottky barrier diode D1 are not shown in FIG. 1A.

The Schottky barrier diode D1 according to the embodiment of the invention includes a one conduction type semiconductor substrate 1, a one conduction type semiconductor layer 2, a trench 5, an insulating film 6, and a Schottky metal layer 9.

A substrate is obtained by stacking the n− type semiconductor layer 2 on the n+ type silicon semiconductor substrate 1 according to, for example, epitaxial growth.

The Schottky metal layer 9 made of Mo or the like, which forms a Schottky junction with a surface of the n− type semiconductor layer 2, is provided on the surface of the n− type semiconductor layer 2. The Schottky metal layer 9 is provided in the opening of an insulating layer 20 formed on the surface of the n− type semiconductor layer 2. A region, where the n− type semiconductor layer 2 and the Schottky metal layer 9 are in contact with each other, is a Schottky junction region 3.

The trench 5 surrounding the Schottky junction region 3 is provided in an outermost periphery of the Schottky junction region 3. The trench 5 is provided to penetrate through the n− type semiconductor layer 2 to reach the n+ type semiconductor substrate 1.

The trench 5 is provided to be deeper than the n− type semiconductor layer 2 according to a breakdown voltage. As an example, when the n− type semiconductor layer 2 has a thickness of about 5 μm to 6 μm, the trench 5 is provided with a depth of 7 μm to 8 μm.

The insulating film 6 is provided at least on an inner wall of the trench 5. In the figure, the insulating film 6 is embedded in the trench 5. Although an oxide film is adopted as the insulating film 6 in this embodiment, the insulating film 6 may be a nitride film or the like instead of the oxide film.

Consequently, when a reverse voltage is applied, expansion in a substrate horizontal direction of a depletion layer is terminated in the trench 5 (the oxide film 6). Note that it is also possible that only the inner wall of the trench 5 is covered by the oxide film 6 and metal such as a part of the Schottky metal layer 9 is embedded in the inside of the trench 5. In this case, the same advantage is obtained.

An anode electrode 10 consisting of a metal layer of Al or the like is provided on the Schottky metal layer 9. A metal layer is also evaporated to provide a cathode electrode 11 on a rear surface of the substrate.

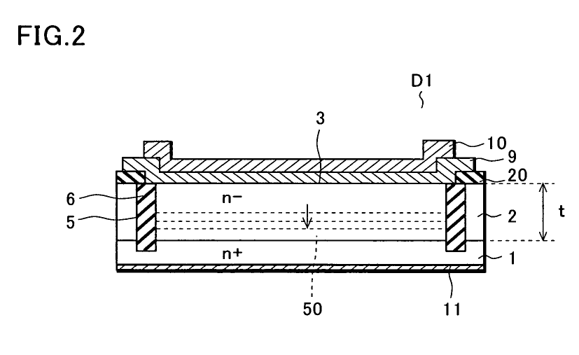

FIG. 2 shows a state in which the depletion layer expands when the reverse voltage is applied.

As described already, the Schottky metal layer 9 is a pseudo p+ type region. An insulated region provided with the oxide film 6 at least on the inner wall of the trench 5 is provided to reach the n+ type substrate 1 in the outermost periphery of the Schottky junction region 3.

When the reverse voltage is applied to the Schottky barrier diode D1, the depletion layer 50 expands to the n− type semiconductor layer 2 according to a Schottky junction of the Schottky metal layer 9 and the n− type semiconductor layer 2.

At this point, the depletion layer 50 is terminated in the trench 5 (the oxide film 6) as indicated by a broken line and expands only in a depth direction of the semiconductor substrate. In other words, an end of the depletion layer 50 does not form a curved surface and does not have a curvature.

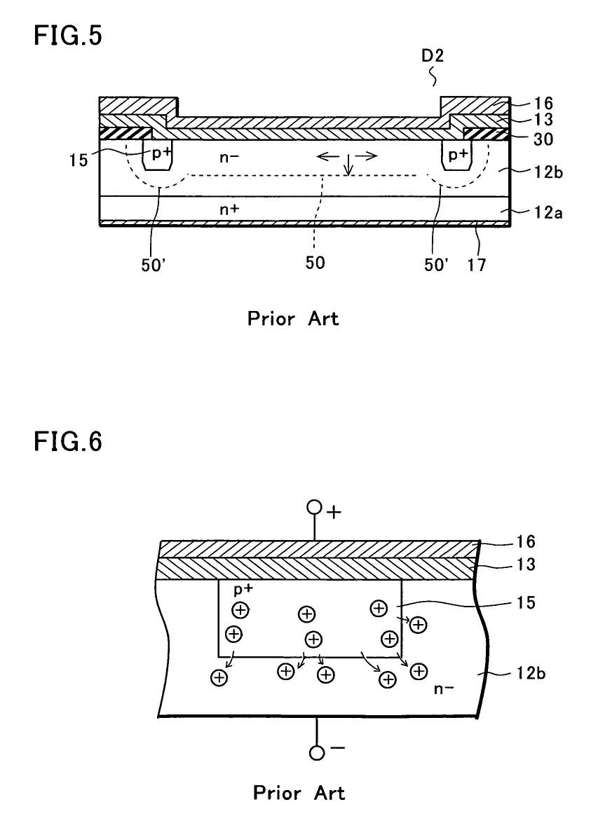

Consequently, the depletion layer 50′, which expands to the periphery of the guard ring 15 (more specifically, a bottom of the guard ring 15 and an outer side of the guard ring 15) in the Schottky barrier diode D2 shown in FIG. 5, is not formed. Thus, it is possible to reduce a capacitance component equivalent to a capacitance of the depletion layer 50′ and realize a reduction in capacitance.

In addition, since the p+ type region constituting the guard ring 15 is made unnecessary, holes (carriers) are never injected when a forward voltage is applied. In other words, since carriers are not accumulated, it is unnecessary to perform outflow or recombination of holes. Therefore, since the reverse recovery time (Trr) is not required, it is possible to improve switching operation speed. More specifically, it is possible to improve the switching operation speed, which is several hundreds ns in the conventional technique, to about several tens ns. In addition, since a loss at the switching time is eliminated, set efficiency is improved.

Moreover, in this embodiment, it is unnecessary to take into account expansion in a substrate horizontal direction of the depletion layer 50. In other words, since thickness and resistivity of the n− type semiconductor layer 2 only have to be controlled in breakdown voltage design, a breakdown voltage is stabilized. Further, since there is no curvature of the depletion layer 50 at the end of the Schottky junction region and a stable breakdown pressure is obtained, it is possible to reduce the forward voltage by reducing resistivity ρ of the n− type semiconductor layer 2. Alternatively, it is possible to reduce the forward voltage by reducing thickness t of the n− type semiconductor layer 2.

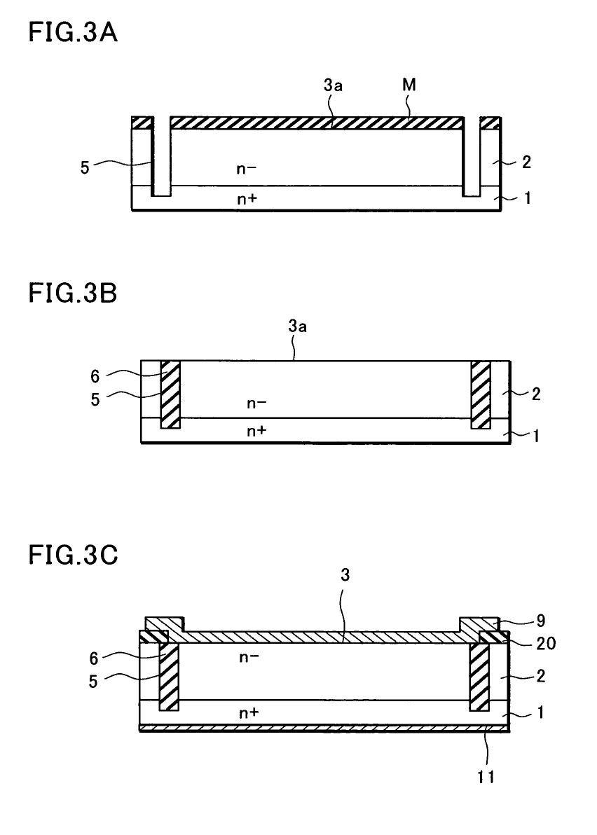

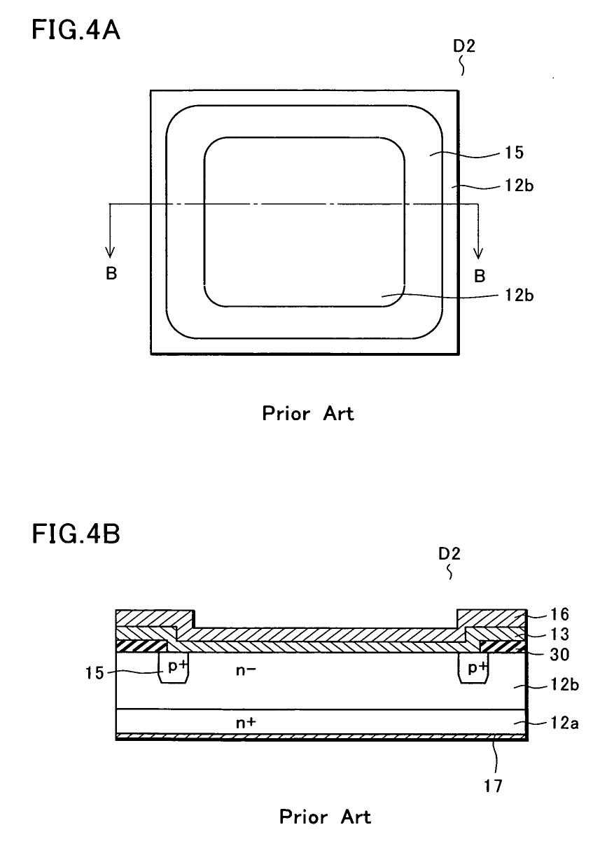

Next, an example of a method of manufacturing a Schottky barrier diode according to an embodiment of the invention will be explained with reference to FIGS. 3A to 3C.

As shown in FIG. 3A, the n− type semiconductor layer 2, which is formed by epitaxial growth or the like, is stacked on the n+ type semiconductor substrate 1. A mask M opened in an outermost periphery of a contact region 3a with a Schottky metal layer, which becomes a Schottky junction region later, is provided. Thereafter, the trench 5, which penetrates through the n− type semiconductor layer 2 to reach the n+ type semiconductor substrate 1, is formed. In other words, the trench 5 is provided in an outermost periphery of the contact region 3a to surround the contact region 3a.

As shown in FIG. 3B, the insulating film 6 such as an oxide film (or a nitride film) is formed inside the trench 5. In other words, the mask M is removed and, then, the oxide film 6 is formed on an entire surface of the substrate. A resist mask is provided only in an upper part of the trench 5 and etched back to embed the oxide film 6 in the trench 5. In this way, a method of embedding the oxide film 6 in the trench 5 is explained. However, it is also possible that the oxide film 6 is provided only on an inner wall of the trench 5 and metal such as a Schottky metal layer is embedded inside the trench 5 in a later process. Consequently, it is possible to secure a stable breakdown voltage when the reverse voltage is applied.

In FIG. 3C, the insulating layer 20 is provided on the surface of the n− type semiconductor layer 2. An opening is formed in the insulating layer 20 and the contact region 3a is exposed. The Schottky metal layer 9 (e.g., Mo), which is in contact with the contact region 3a and a part of the oxide film 6 exposed in an opening of the trench 5, is evaporated. Consequently, the contact region 3a serves as the Schottky junction region 3 of the Schottky metal layer 9 and the n− type semiconductor layer 2. After patterning the Schottky metal layer 9 into a desired shape covering at least the Schottky junction region 3, the Schottky metal layer 9 is subjected to annealing at 500 to 600° C. for siliciding. Here, for example, when a predetermined forward voltage is not obtained, Ni, Cr, Ti, or the like with low φBn is used instead of Mo.

Thereafter, an Al layer, which servers as the anode electrode 10, is evaporated on an entire surface of the Schottky metal layer 9 and patterned in a desired shape. The cathode electrode 11 of Ti/Ni/Au, or the like is formed on a rear surface of the n+ type semiconductor substrate 1 to obtain a final structure shown in FIGS. 1A and 1B.

According to the embodiment of the invention, since the expansion of the depletion layer becomes uniform at the end and near the center of the Schottky junction region, it is possible to obtain a stable breakdown voltage.

Since an oxide film (the trench) is provided to reach the n+ type substrate, the depletion layer expanding to the periphery of the guard ring in the conventional technique is eliminated to make it possible to realize a reduction in capacitance.

Moreover, since the p+ type region constituting the guard ring is made unnecessary, holes are never injected when the forward voltage is applied. In other words, since carriers are not accumulated, it is unnecessary to perform the outflow or the recombination of holes. Therefore, since the reverse recovery time (Trr) is not required, it is possible to improve switching operation speed. More specifically, it is possible to improve the switching operation speed, which is several hundreds ns in the conventional technique, to about several tens ns. In addition, since a loss at the switching time is eliminated, set efficiency is improved.

1. A semiconductor device comprising:
a semiconductor substrate;
a semiconductor layer disposed on the substrate;
a metal layer forming a Schottky junction with the semiconductor layer to define a Schottky region; and
a trench formed in the semiconductor layer to surround the Schottky region and reaching the semiconductor substrate, an inner wall of the trench being covered by an insulating film.

2. The semiconductor device of claim 1, wherein the insulating film fills the trench.

3. The semiconductor device of claim 1, wherein the metal layer fills at least partially the trench, the inner wall of which is covered by the insulating film.

4. The semiconductor device of claim 1, wherein the trench is configured to prevent an depletion layer formed under a reverse voltage applied between the metal layer and the semiconductor layer from expanding beyond the Schottky region.

5. The semiconductor device of claim 1, wherein the trench is configured to limit an expansion of a depletion layer formed under a reverse voltage applied between the metal layer and the semiconductor layer to a direction normal to the semiconductor layer.
